(19) United States
(12) Patent Application Publication
(10) Pub. No.: US 2026/0371499 A1
(43) Pub. Date: Nov. 19, 2026

(54) METHOD AND APPARATUS FOR FORMING A CONDUCTIVE STRUCTURE

(71) Applicant: CohPros International Co., Ltd., Hsinchu City (TW)

(72) Inventors: SHIH-SHENG LIN, Kaohsiung City (TW); CHIH-WEI YU, Taipei City (TW)

(21) Appl. No.: 19/676,959

(22) Filed: May 14, 2026

(30) Foreign Application Priority Data
May 15, 2025 (TW) 114118178

(51) Int. Cl. H05K 3/40; G06T 7/00

(52) U.S. Cl. CPC H05K 3/4061; G06T 7/001; G06T 2207/20081; G06T 2207/30141; H05K 2203/107; H05K 2203/1131; H05K 2203/163

(57) ABSTRACT

A method and an apparatus for forming a conductive structure. The method for forming the conductive structure includes the following steps: carrying at least one substrate by a carrying module, in which the at least one substrate has a plurality of through holes; providing a plurality of conductive materials to be solidified into the plurality of through holes by a plurality of nozzle elements of a feeding module; and providing a plurality of laser beams into the plurality of through holes to solidify the plurality of conductive materials to be solidified by at least one laser module. Accordingly, the method and the apparatus for forming the conductive structure of the present disclosure can not only improve a connection yield between conductive posts and inner wall surfaces of holes, but also provide a simple and environmentally friendly process.

### CROSS-REFERENCE TO RELATED PATENT APPLICATION

This application claims the benefit of priority to Taiwan Patent Application No. 114118178, filed on May 15, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a method and an apparatus for forming a conductive structure, and more particularly to a method and an apparatus for forming a conductive structure by filling a non-solid conductive material.

### BACKGROUND OF THE DISCLOSURE

In the technical field of semiconductor substrates, an electroplating technique is generally used to form conductive posts in through holes and blind holes of a substrate. However, the electroplating technique not only has relatively high difficulty and complexity, but also does not provide a tight connection between the conductive posts and inner wall surfaces of the holes, and is not environmentally friendly.

### SUMMARY OF THE DISCLOSURE

In response to the above-referenced technical inadequacy, the present disclosure provides a method and an apparatus for forming a conductive structure.

In order to solve the above-mentioned problems, one of the technical aspects adopted by the present disclosure is to provide a method for forming a conductive structure, which includes: carrying at least one substrate by a carrying module, in which the at least one substrate has a plurality of through holes; providing a plurality of conductive materials to be solidified into the plurality of through holes by a plurality of nozzle elements of a feeding module; and providing a plurality of laser beams into the plurality of through holes to solidify the plurality of conductive materials to be solidified by at least one laser module.

In order to solve the above-mentioned problems, another one of the technical aspects adopted by the present disclosure is to provide an apparatus for forming a conductive structure, which includes a carrying module, a feeding module and at least one laser module. The carrying module is configured to carry at least one substrate, and the at least one substrate has a plurality of through holes. The feeding module has a plurality of nozzle elements, and the plurality of nozzle elements are configured to provide a plurality of conductive materials to be solidified into the plurality of through holes, respectively. The at least one laser module is configured to provide a plurality of laser beams into the plurality of through holes to solidify the plurality of conductive materials to be solidified.

One advantageous effect of the present disclosure is that, through the above technical solution, the method and the apparatus for forming the conductive structure provided by the present disclosure can not only improve a connection yield or a bonding yield between conductive posts and inner wall surfaces of holes, but also provide a simple and environmentally friendly process.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for forming a conductive structure according to a first embodiment of the present disclosure;

FIG. 2 is a schematic diagram showing a use state of an apparatus for forming a conductive structure according to the first embodiment of the present disclosure;

FIG. 3 is a schematic diagram showing a use state of a monitoring module of the apparatus for forming the conductive structure according to the first embodiment of the present disclosure;

FIG. 4 is a functional block diagram of the apparatus for forming the conductive structure according to the first embodiment of the present disclosure;

FIG. 5 is a flowchart of a method for forming a conductive structure according to a second embodiment of the present disclosure;

FIG. 6 is a schematic diagram of a forming image of the method and the apparatus for forming the conductive structure according to an embodiment of the present disclosure; and

FIG. 7 is a partially enlarged schematic diagram of the forming image of FIG. 6.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like. It should be noted that the examples provided in the following description are merely illustrative embodiments and are not intended to limit the scope of the present disclosure.

### First Embodiment

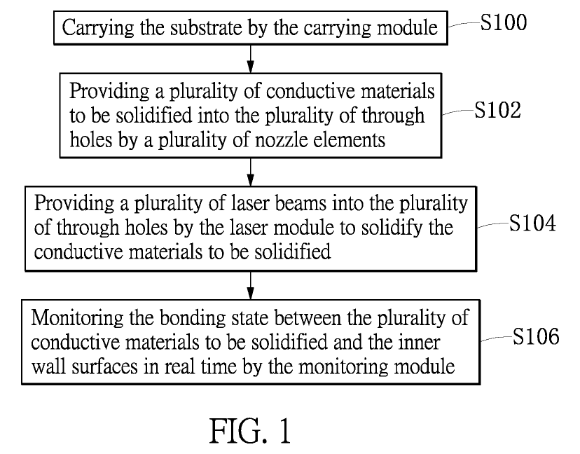

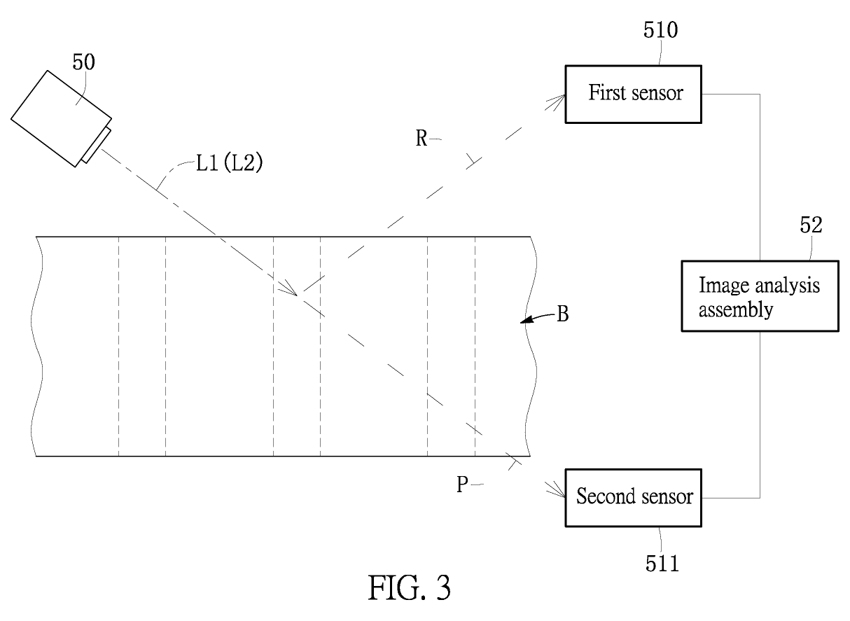

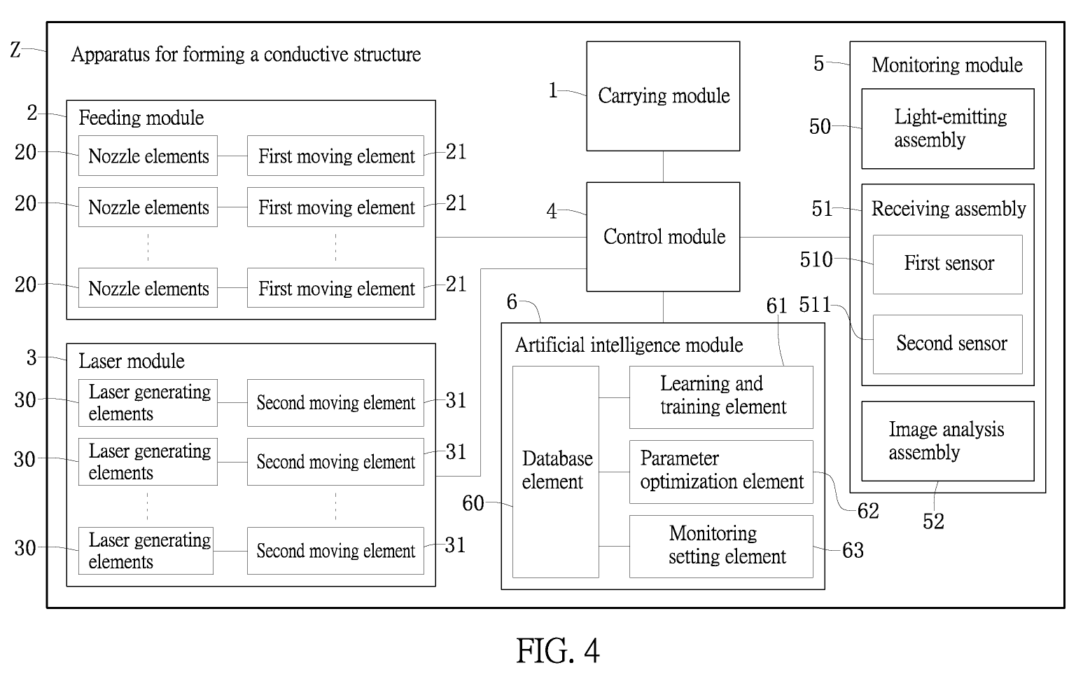

Referring to FIGS. 1-4, a first embodiment of the present disclosure provides a method for forming a conductive structure, which may include the following steps.

First, at least one substrate B may be carried by a carrying module 1. For example, as shown in FIGS. 1, 2, and 4, the carrying module 1 may be a two-dimensionally movable or three-dimensionally movable stage device, in which the carrying module 1 may also have at least one opening (not labeled in the drawings) passing through a body of the carrying module 1. One surface of the carrying module 1 is used for carrying the substrate B. The substrate B may be a glass substrate or a substrate made of another transparent material, and may have a plurality of through holes B1. The substrate B may further have an inner wall surface B2 corresponding to each through hole B1 (that is to say, the substrate B has a plurality of inner wall surfaces B2).

Next, a plurality of conductive materials to be solidified C may be provided into the plurality of through holes B1 by a plurality of nozzle elements of a feeding module 2. For example, as shown in FIGS. 1, 2, and 4, the feeding module 2 may be two-dimensionally movable or three-dimensionally movable feeding equipment, which may be adjacent to the carrying module 1 or suspended on the carrying module 1. The feeding module 2 may include a plurality of nozzle elements 20 and at least one first moving element 21. Each of the plurality of nozzle elements 20 may correspond to one of the through holes B1 and be used to provide the conductive materials to be solidified C, in which the conductive material to be solidified C may be a viscous or thick metal paste, such as silver paste, but is not limited thereto. Therefore, the plurality of nozzle elements 20 of the feeding module 2 may separately or simultaneously inject the conductive material to be solidified C into the through holes B1, and may slowly and continuously inject a small amount of the conductive material to be solidified C into the through holes B1. The at least one first moving element 21 may be connected to the plurality of nozzle elements 20. The first moving element 21 may be a position adjustment mechanism assembly or another type of adjustment mechanism assembly. The at least one first moving element 21 may be configured to drive and adjust a position of each of the plurality of nozzle elements 20. Therefore, a positional arrangement of the plurality of nozzle elements 20 may depend on positions of the plurality of through holes B1 on the substrate B. By manual control or sensor detection, the first moving element 21 can be configured to adjust a spacing g between two adjacent nozzle elements 20, thereby allowing each of the plurality of nozzle elements 20 to correspond to one of the through holes B1. The plurality of nozzle elements 20 may be arranged in a linear manner or in a planar manner. It is worth mentioning that, in the present embodiment, a plurality of first moving elements 21 are provided and correspond to the nozzle elements 20 in a one-to-one manner, but the present disclosure is not limited thereto. In practical application, positions of the plurality of nozzle elements 20 may also be adjusted by a single first moving element 21.

Next, a plurality of laser beams L may be provided into the plurality of through holes B1 by at least one laser module 3 to solidify the plurality of conductive materials to be solidified C. For example, as shown in FIGS. 1, 2, and 4, , the laser module 3 may be two-dimensionally movable or three-dimensionally movable laser equipment, which may be adjacent to the carrying module 1 or the feeding module 2, or may be suspended on the carrying module 1, in which the laser module 3 may be located on a same side of the carrying module 1 as the feeding module 2, or may be located on a different side of the carrying module 1 from the feeding module 2. The laser module 3 may include a plurality of laser generating elements 30 and at least one second moving element 31. Each laser generating element 30 may be a laser beam generator or another similar device, and may be configured to provide the laser beam L into the corresponding through hole B1. Therefore, during a process in which the feeding module 2 injects the conductive material to be solidified C into the through hole B1, the laser module 3 may simultaneously project the laser beam L into the through hole B1 to solidify the conductive material to be solidified C. The at least one second moving element 31 may be connected to the plurality of laser generating elements 30. The second moving element 31 may be a position adjustment mechanism assembly or another type of adjustment mechanism assembly. The at least one second moving element 31 may be configured to drive and adjust a position of each laser generating element 30. Therefore, a positional arrangement of the plurality of laser generating elements 30 may depend on positions of the plurality of through holes B1 on the substrate B. By manual control or sensor detection, the second moving element 31 adjusts a spacing between two adjacent laser generating elements 30, in a manner similar to the adjustment manner of the first moving element 21 described above and therefore not specifically described herein, thereby allowing each laser generating element 30 to correspond to one of the through holes B1. The plurality of laser generating elements 30 may also be arranged in a linear manner or in a planar manner. It is worth mentioning that, in the present embodiment, a plurality of second moving elements 31 are provided and correspond to the laser generating elements 30 in a one-to-one manner, but the present disclosure is not limited thereto. In practical application, positions of the plurality of laser generating elements 30 may also be adjusted by a single second moving element 31. In addition, in other optional embodiments, the present disclosure may also use a single laser module 3, namely the laser generating element 30, to generate a plurality of laser beams L and project the laser beams L into the plurality of through holes B1, so as to solidify the conductive material to be solidified C in each through hole B1.

Furthermore, during a process in which the plurality of nozzle elements 20 of the feeding module 2 inject the conductive material to be solidified C into the through hole B1 in small amounts and in a continuous or intermittent manner, because the conductive material to be solidified C is gel-like, viscous, and semi-liquid, the conductive material to be solidified C tightly contacts and is connected to the inner wall surface B2 of the substrate B. The conductive material to be solidified C is then irradiated by the laser beam L projected by the laser generating element 30, in which the plurality of laser generating elements 30 of the laser module 3 may cooperate with a feeding mode of the plurality of nozzle elements 20 of the feeding module 2 to project or direct the laser beam L in a continuous or intermittent manner to irradiate the conductive material to be solidified C. During a process in which the conductive material to be solidified C is gradually solidified, moisture in the conductive material to be solidified C is evaporated and the conductive material to be solidified C is tightly connected to the inner wall surface B2, such that the solidified conductive material to be solidified C has substantially no moisture. In addition, the solidified conductive material to be solidified C fills a part of a space of the through hole B1, and is tightly connected to the inner wall surface B2 such that there is completely or substantially no gap or void between the solidified conductive material to be solidified C and the inner wall surface B2. Then, the feeding module 2 may again supply the conductive material to be solidified C on the solidified conductive material to be solidified C, and the at least one laser module 3 may again project or direct the laser beam L to irradiate the conductive material to be solidified C.

By the above manner, multiple layers of the solidified conductive material to be solidified C may be formed in each through hole B1. Finally, after each conductive material to be solidified C fills the corresponding through hole B1 and is solidified, the multiple layers of the solidified conductive material to be solidified C may form a conductive member C1, in which each of the plurality of conductive members C1 may be a single component having a multilayer structure.

Accordingly, the method for forming the conductive structure of the present disclosure may, through the above technical solution, use the feeding module 2 to fill the thickened conductive material to be solidified C into the plurality of through holes B1, and simultaneously use the laser module 3 to project or direct the plurality of laser beams L to irradiate the conductive materials to be solidified C in the plurality of through holes B1, so as to sequentially or simultaneously form a plurality of conductive members C1, each being a single component, in the plurality of through holes B1 by a 3D shaping manner. Each of the plurality of conductive members C1 may be tightly connected to the inner wall surface B2 of the substrate B, and there is no pore, gap, or void therebetween. In addition, while the conductive material to be solidified C is solidified, moisture in the conductive material to be solidified C can also be removed, such that the solidified conductive material to be solidified C has a tight and firm structure.

Furthermore, after the step of solidifying the conductive material to be solidified C, the method for forming the conductive structure of the present disclosure may further include the following step.

A monitoring module 5 can be configured to monitor, in real time, a bonding state between the plurality of conductive materials to be solidified C and the corresponding inner wall surfaces B2. For example, as shown in FIGS. 1-4, while or after the conductive material to be solidified C is solidified, the method for forming the conductive structure of the present disclosure may further use the monitoring module 5 to inspect a position where the solidified conductive material to be solidified C is connected to the inner wall surface B2.

Furthermore, in the step in which the monitoring module 5 performs real-time monitoring, the method for forming the conductive structure of the present disclosure may further include the following steps.

A light-emitting assembly 50 can be configured to emit at least one first laser inspection beam L1 and at least one second laser inspection beam L2 toward the at least one substrate B.

A first sensor 510 can be configured to receive a reflected light R of the at least one first laser inspection beam L1 reflected by the at least one substrate B to generate a reflected signal.

A second sensor 511 can be configured to receive a transmitted light P of the at least one second laser inspection beam L2 passing through the at least one substrate B to generate a transmitted signal.

An image analysis assembly 52 can be configured to receive the reflected signal and generate first inspection image data, and receive the transmitted signal and generate second inspection image data.

For example, as shown in FIGS. 1-4, the monitoring module 5 may include a light-emitting assembly 50, a receiving assembly 51, and an image analysis assembly 52. The light-emitting assembly 50 may provide a laser that emits the at least one first laser inspection beam L1 and the at least one second laser inspection beam L2 toward the at least one substrate B, in which wavelength ranges of the first laser inspection beam L1 and the second laser inspection beam L2 may be between 300 nm and 2000 nm (such as any positive integer between 300 nm and 2000 nm), and pulse width ranges of the first laser inspection beam L1 and the second laser inspection beam L2 may be between 50 fs and 50 ns (such as any positive integer between 50 fs and 50 ns). The receiving assembly 51 may include a first sensor 510 and a second sensor 511. The first sensor 510 may be located on a first side of the at least one substrate B. The first sensor 510 may be used to receive the reflected light R of the first laser inspection beam L1 reflected by the at least one substrate B to generate the reflected signal. The second sensor 511 may be located on a second side of the at least one substrate B. The light-emitting assembly 50 can emit the second laser inspection beam L2 toward the at least one substrate B. The second sensor 511 may be used to receive the transmitted light P of the second laser inspection beam L2 passing through the at least one substrate B to generate the transmitted signal. The image analysis assembly 52 may be electrically connected to the first sensor 510 and the second sensor 511. The image analysis assembly 52 may be configured to receive the reflected signal and generate the first inspection image data, and to receive the transmitted signal and generate the second inspection image data.

When the image analysis assembly 52 is a waveform generator, the first sensor 510 and the second sensor 511 may be optical wavefront sensors. Therefore, the first inspection image data generated by the image analysis assembly 52 may be a first inspection waveform diagram, and the second inspection image data may be a second inspection waveform diagram. Alternatively, the first sensor 510 and the second sensor 511 may also be laser vibrometers, the reflected signal is a reflected ultrasound signal, and the transmitted signal is a transmitted ultrasound signal. Therefore, the first inspection image data generated by the image analysis assembly 52 may be a first waveform diagram, and the second inspection image data may be a second waveform diagram.

In other optional embodiments, the first sensor 510 and the second sensor 511 may also be photoelastic sensors. Therefore, the first inspection image data generated by the image analysis assembly 52 may be a first stress distribution characteristic image, and the second inspection image data may be a second stress distribution characteristic image.

In other optional embodiments, the first sensor 510 and the second sensor 511 may also be hyperspectral sensors, and the image analysis assembly 52 may be a hyperspectral generator or a hyperspectral analysis device. Therefore, the first inspection image data generated by the image analysis assembly 52 may be a first inspection spectrum diagram, and the second inspection image data may be a second inspection spectrum diagram, in which a spectrum received by the hyperspectral sensor (i.e., the image analysis assembly 52) is a continuous spectrum, and a spectral range is between 300 nm and 2500 nm.

It should be noted that the first sensor 510 of the present disclosure may also be connected to a first moving device M1, so that the first sensor 510 is moved in a three-dimensional space by being driven by the first moving device M1. In addition, the second sensor 511 may also be connected to a second moving device M2, so that the second sensor 511 is moved in the three-dimensional space by being driven by the second moving device M2. Moreover, the light-emitting assembly 50 may also be connected to a laser moving device M3, so that the light-emitting assembly 50 is moved in the three-dimensional space by being driven by the laser moving device M3.

In addition, according to the above contents and as shown in FIGS. 1-4, the present disclosure further provides an apparatus Z for forming a conductive structure, which may include a carrying module 1, a feeding module 2, and at least one laser module 3. The carrying module 1 may be configured to carry at least one substrate B, in which the at least one substrate B may have a plurality of through holes B1. The feeding module 2 may have a plurality of nozzle elements 20, and the plurality of nozzle elements 20 may be configured to provide a plurality of conductive materials to be solidified C into the plurality of through holes B1. The at least one laser module 3 may be configured to provide a plurality of laser beams L into the plurality of through holes B1 to solidify the plurality of conductive materials to be solidified C.

Furthermore, the plurality of nozzle elements 20 may be configured to provide the plurality of conductive materials to be solidified C into the plurality of through holes B1 in a continuous or intermittent manner, so as to gradually fill the plurality of through holes B1. The at least one laser module 3 may be configured to project or direct the plurality of laser beams L to the plurality of conductive materials to be solidified C in a continuous or intermittent manner, so that the plurality of conductive materials to be solidified C that are filled into the plurality of through holes B1 are gradually solidified to form a plurality of conductive members C1. Each of the plurality of conductive members C1 may be a single component having a multilayer structure. The at least one substrate B may have an inner wall surface B2 corresponding to each through hole B1. When each conductive material to be solidified C is gradually solidified, each conductive material to be solidified C may contact the corresponding inner wall surface B2 and be tightly connected to the inner wall surface B2.

Furthermore, the feeding module 2 may include the plurality of nozzle elements 20 and at least one first moving element 21. Each of the plurality of nozzle elements 20 may correspond to one of the through holes B1. The at least one first moving element 21 is connected to the plurality of nozzle elements 20. The at least one first moving element 21 may be configured to drive and adjust a position of each of the plurality of nozzle elements 20, in which the plurality of nozzle elements 20 may be arranged in a linear manner or in a planar manner. The at least one laser module 3 may include the plurality of laser generating elements 30 and at least one second moving element 31. Each laser generating element 30 may be configured to provide the laser beam L into the corresponding through hole B1. The at least one second moving element 31 is connected to the plurality of laser generating elements 30. The at least one second moving element 31 may be configured to drive and adjust a position of each laser generating element 30, in which the plurality of laser generating elements 30 are arranged in a linear manner or in a planar manner.

Furthermore, the apparatus Z for forming the conductive structure may further include a control module 4 and a monitoring module 5. The control module 4 may be electrically connected to the carrying module 1, the plurality of nozzle elements 20, the at least one first moving element 21, the plurality of laser generating elements 30, and the at least one second moving element 31. The control module 4 may be a control device, a backend control center, or a remote server, but is not limited thereto. The control module 4 may be configured to control an operating state of at least one of the carrying module 1, the plurality of nozzle elements 20, the at least one first moving element 21, the plurality of laser generating elements 30, the at least one second moving element 31, and the monitoring module 5. The monitoring module 5 may be electrically connected to the control module 4. The monitoring module 5 may be configured to monitor a solidification state of the conductive material to be solidified C and a connection state between the conductive material to be solidified C and the inner wall surface B2. The monitoring module 5 may use a plurality of laser inspection beams having different delay times, namely the first laser inspection beam L1 and the second laser inspection beam L2, to probe morphological parameters of the at least one substrate B, so as to monitor, in real time, a bonding state between the inner wall surface B2 of the at least one substrate B and the conductive material to be solidified C. A specific implementation of the monitoring module 5 has been described in the implementation process of the foregoing method for forming the conductive structure, and therefore is not specifically described herein again.

It is worth mentioning that the apparatus Z for forming the conductive structure of the present disclosure may further include the first moving device M1, the second moving device M2, and the laser moving device M3. The first moving device M1, the second moving device M2, and the laser moving device M3 may be three-dimensional moving equipment.

Furthermore, the apparatus Z for forming the conductive structure may further include an artificial intelligence module 6, which is used to learn and pre-train laser parameters of the laser module 3, automatically select a suitable monitoring module 5 according to characteristics of the at least one substrate B, and optimize settings of at least one monitoring parameter of the monitoring module 5.

For example, the artificial intelligence module 6 may include a database element 60, a learning and training element 61, a parameter optimization element 62, and a monitoring setting element 63. The database element 60 may have relevant data regarding a type, shape, size, thickness, and density of the at least one substrate B, in which the database element 60 may be connected to a cloud platform through the Internet to update the relevant data. The learning and training element 61 may be connected to the database element 60. The learning and training element 61 may perform learning and pre-training using a deep learning algorithm according to the relevant data in the database element 60. The parameter optimization element 62 may be connected to the database element 60, so as to optimize settings of the laser parameter according to the relevant data regarding the type, shape, size, thickness, and density of the at least one substrate B. The monitoring setting element 63 may be connected to the database element 60, so as to adjust the at least one monitoring parameter of the monitoring module 5 according to the relevant data regarding the type, shape, size, thickness, and density of the at least one substrate B.

However, the above example is merely one feasible embodiment and is not intended to limit the present disclosure.

### Second Embodiment

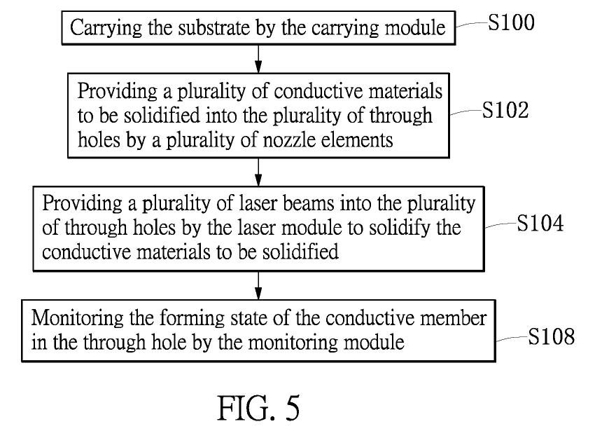

Referring to FIGS. 5-7, and also referring to FIGS. 1-4, as shown in the drawings, the method and the apparatus for forming the conductive structure of the present embodiment are substantially similar to the method and the apparatus for forming the conductive structure of the first embodiment described above. Therefore, arrangements or operations of the same elements are not repeated herein. A difference between the present embodiment and the first embodiment described above is that, in the present embodiment, after the step of solidifying the conductive material to be solidified C, the method for forming the conductive structure of the present disclosure may further include the following step.

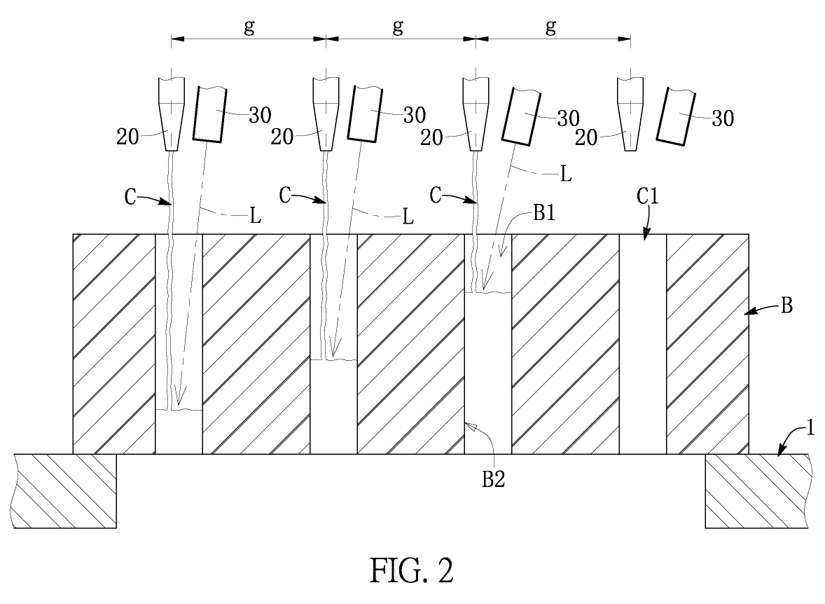

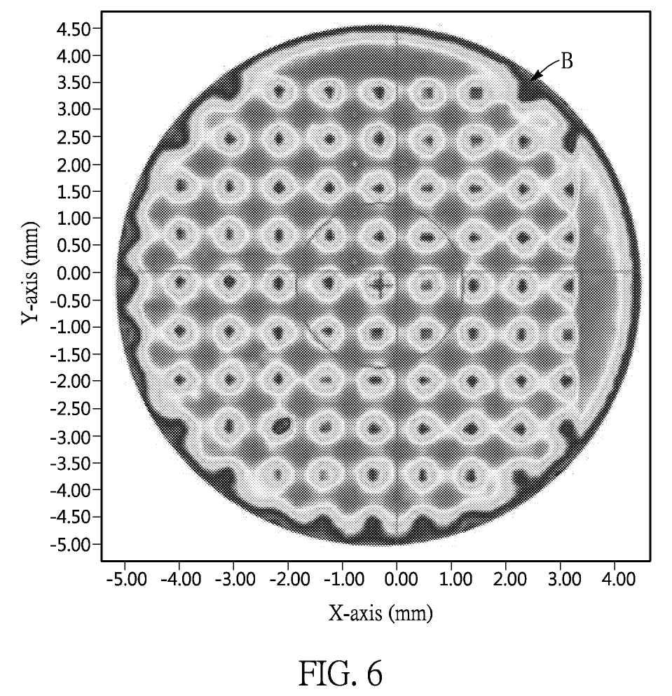

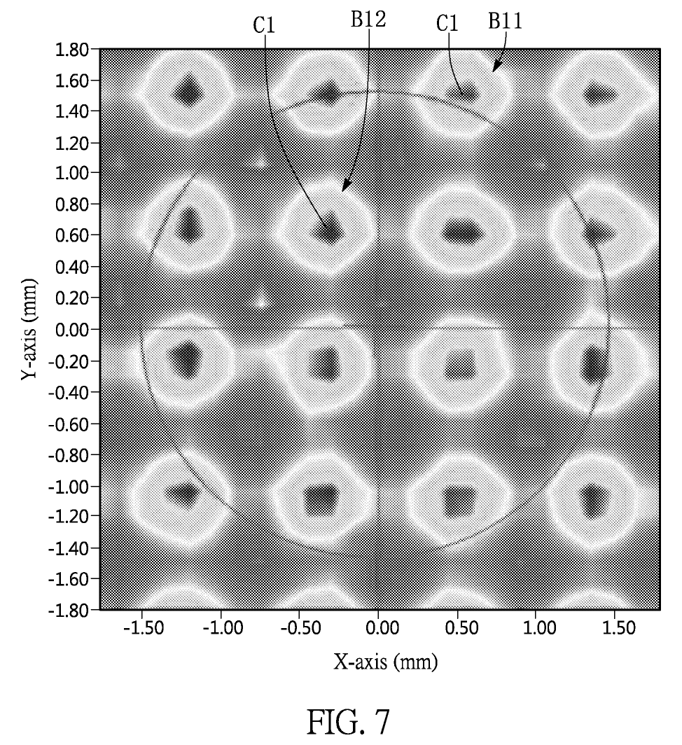

A monitoring module is used to monitor a forming state of the conductive member C1 in at least one through hole B1. For example, as shown in FIGS. 2, 4, and 5-7, while or after the conductive material to be solidified C is solidified, the method for forming the conductive structure of the present disclosure may further use the monitoring module 5 to inspect the through hole B1 in which the conductive member C1 is formed. Furthermore, the monitoring module 5 of the present disclosure may be an image capturing device, and may be suspended on one surface of the substrate B, namely above the substrate B. The monitoring module 5 may be configured to capture an image of the at least one through hole B1 or the substrate B, and obtain a forming image, as shown in FIGS. 6 and 7. The monitoring module 5 or the control module 4 may store a plurality of preset finished-product images, including images of the substrate B and the through hole B1 without defects. Therefore, after the conductive member C1 is formed in the at least one through hole B1 of the substrate B, the monitoring module 5 may be used to inspect the forming state of the conductive member C1 in the through hole B1, such as whether the through hole B1 is completely or substantially filled or whether forming is complete, such as having a preset specific specification size. The monitoring module 5 or the control module 4 may compare the forming image with the preset finished-product images. When it is determined that an image of one through hole B1 in the forming image does not conform to a reference through-hole image in the preset finished-product images, the through hole B1 is determined to be a defective through hole B11. When it is determined that the image of one through hole B1 in the forming image conforms to the through-hole image in the preset finished-product images, the through hole B1 is determined to be a non-defective through hole B12.

Therefore, when the monitoring module 5 or the control module 4 determines that one or more through holes B1 of the substrate B are defective through holes B11, the control module 4 may drive the feeding module 2 to provide the conductive materials to be solidified C to the defective through holes B11, and drive the laser module 3 to project or direct the laser beam L into the defective through holes B11, so as to solidify the conductive material to be solidified C filled again by the feeding module 2.

It should be noted that the control module 4 may determine an injection amount of the conductive material to be solidified C provided by the feeding module 2 to the defective through hole B11 according to a difference between the forming image and the preset finished-product images, such as a size of a color block in the forming image, but not limited thereto. In addition, the control module 4 may obtain material-to-be-supplemented position information according to a position of the defective through hole B11 corresponding to the forming image. Moreover, the control module 4 may also preset and store nozzle position information of each of the plurality of nozzle elements 20 of the feeding module 2. Then, according to the material-to-be-supplemented position information and the plurality of pieces of nozzle position information, the control module 4 may drive the nozzle element 20 corresponding to the defective through hole B11 to provide the conductive materials to be solidified C into the defective through hole B11.

### Beneficial Effects of the Embodiments

One advantageous effect of the present disclosure is that, through the above technical solution, the method and the apparatus for forming the conductive structure provided by the present disclosure can not only improve a connection yield between conductive posts and inner wall surfaces of holes, but also provide a simple and environmentally friendly process.

Furthermore, the method for forming the conductive structure and the apparatus Z for forming the conductive structure of the present disclosure may use the feeding module 2 to fill the thickened plurality of conductive materials to be solidified C into the plurality of through holes B1, and simultaneously use the laser module 3 to project or direct the plurality of laser beams L to irradiate the conductive materials to be solidified C in the plurality of through holes B1, so as to sequentially or simultaneously form a plurality of conductive members C1, each being a single component, in the plurality of through holes B1 by a 3D shaping manner. Each of the plurality of conductive members C1 may be tightly connected to the inner wall surface B2 of the substrate B, and there is no pore, gap, or void therebetween. In addition, while the conductive material to be solidified C is solidified, moisture in the conductive material to be solidified C can also be removed, such that the solidified conductive material to be solidified C has a tight and firm structure. Moreover, the method for forming the conductive structure and the apparatus Z for forming the conductive structure of the present disclosure may further monitor, in real time, the bonding state between the conductive material to be solidified C and the inner wall surface B2 through the monitoring module 5, and cooperate with regulation and control of the artificial intelligence module 6 to improve forming stability of the conductive member C1 and tight bonding between the conductive member C1 and the inner wall surface B2.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for forming a conductive structure, comprising:
carrying at least one substrate by a carrying module, wherein the at least one substrate has a plurality of through holes;
providing a plurality of conductive materials to be solidified into the plurality of through holes by a plurality of nozzle elements of a feeding module; and
providing a plurality of laser beams into the plurality of through holes to solidify the plurality of conductive materials to be solidified by at least one laser module.

2. The method according to claim 1, wherein, in the step of providing the plurality of conductive materials to be solidified into the plurality of through holes, the plurality of nozzle elements are configured to provide the plurality of conductive materials to be solidified into the plurality of through holes in a continuous or intermittent manner to gradually fill the plurality of through holes, and the at least one laser module is configured to project the plurality of laser beams onto the plurality of conductive materials to be solidified in a continuous or intermittent manner, so that the plurality of conductive materials to be solidified that are filled into the plurality of through holes are gradually solidified to form a plurality of conductive members through the plurality of laser beams, each of the plurality of conductive members being a single component having a multilayer structure.

3. The method according to claim 2,
wherein the at least one substrate has a plurality of inner wall surfaces respectively corresponding to the plurality of through holes; and
wherein, during a process in which each of the plurality of conductive materials to be solidified is gradually solidified, each of the plurality of conductive materials to be solidified is tightly connected to a corresponding one of the plurality of inner wall surfaces.

4. The method according to claim 3, further comprising: monitoring a bonding state between each of the plurality of conductive materials to be solidified and the corresponding one of the plurality of inner wall surfaces in real time by a monitoring module.

5. The method according to claim 4, wherein the monitoring module comprises:
a light-emitting assembly configured to emit at least one first laser inspection beam and at least one second laser inspection beam toward the at least one substrate;
a first sensor configured to receive a reflected light of the at least one first laser inspection beam reflected by the at least one substrate to generate a reflected signal;
a second sensor configured to receive a transmitted light of the at least one second laser inspection beam passing through the at least one substrate to generate a transmitted signal; and
an image analysis assembly configured to receive the reflected signal to generate first inspection image data and receive the transmitted signal to generate second inspection image data.

6. The method according to claim 5,
wherein wavelength ranges of the at least one first laser inspection beam and the at least one second laser inspection beam are between 300 nm and 2000 nm; and
wherein pulse width ranges of the at least one first laser inspection beam and the at least one second laser inspection beam are between 50 fs and 50 ns.

7. The method according to claim 5,
wherein the first sensor and the second sensor are hyperspectral sensors;
wherein the image analysis assembly is a hyperspectral generator or a hyperspectral analysis device; and
wherein the first inspection image data and the second inspection image data respectively comprise a first inspection spectrum diagram and a second inspection spectrum diagram.

8. The method according to claim 1, further comprising: monitoring a forming state of the plurality of conductive materials to be solidified in the plurality of through holes respectively by a monitoring module;
wherein the monitoring module is configured to capture an image of at least one of the plurality of through holes to obtain a forming image;
wherein, when the monitoring module is configured to determine that the forming image conforms to a preset finished-product image, the monitoring module is configured to determine that the at least one of the plurality of through holes is a non-defective through hole; and
wherein, when the monitoring module is configured to determine that the forming image does not conform to the preset finished-product image, the monitoring module is configured to determine that the at least one of the plurality of through holes is a defective through hole.

9. The method according to claim 8, wherein, when the monitoring module determines that one or more of the plurality of through holes are defective through holes, a control module drives the feeding module to provide the conductive materials to be solidified into the defective through holes, and drives the at least one laser module to project the plurality of laser beams into the defective through holes so as to solidify the conductive material to be solidified that is refilled into the defective through holes.

10. The method according to claim 9, wherein the control module determines an injection amount of the conductive material to be solidified provided into the defective through holes according to a difference between the forming image and the preset finished-product image.

11. An apparatus for forming a conductive structure, comprising:
a carrying module configured to carry at least one substrate, wherein the at least one substrate has a plurality of through holes;
a feeding module having a plurality of nozzle elements, wherein the plurality of nozzle elements are configured to provide a plurality of conductive materials to be solidified into the plurality of through holes, respectively; and
at least one laser module configured to provide a plurality of laser beams into the plurality of through holes to solidify the plurality of conductive materials to be solidified.

12. The apparatus according to claim 11,
wherein the plurality of nozzle elements are configured to provide the plurality of conductive materials to be solidified into the plurality of through holes respectively in a continuous or intermittent manner, so as to gradually fill the plurality of through holes;
wherein the at least one laser module is configured to project the plurality of laser beams onto the plurality of conductive materials to be solidified in a continuous or intermittent manner, so that the plurality of conductive materials to be solidified that are filled into the plurality of through holes are gradually solidified to form a plurality of conductive members, each of the plurality of conductive members being a single component having a multilayer structure;
wherein the at least one substrate has a plurality of inner wall surfaces respectively corresponding to the plurality of through holes; and
wherein, when each of the plurality of conductive materials to be solidified is gradually solidified, each of the plurality of conductive materials to be solidified is tightly connected to a corresponding one of the plurality of inner wall surfaces.

13. The apparatus according to claim 12,
wherein the feeding module includes at least one first moving element, each of the plurality of nozzle elements corresponds to one of the plurality of through holes, the at least one first moving element is connected to the plurality of nozzle elements, and the at least one first moving element is configured to drive and adjust a position of each of the plurality of nozzle elements;
wherein the plurality of nozzle elements are arranged in a linear manner or in a planar manner;
wherein the at least one laser module includes a plurality of laser generating elements and at least one second moving element, each of the plurality of laser generating elements is configured to provide the laser beam into the corresponding one of the plurality of through holes, the at least one second moving element is connected to the plurality of laser generating elements, and the at least one second moving element is configured to drive and adjust a position of each of the plurality of laser generating elements; and
wherein the plurality of laser generating elements are arranged in a linear manner or in a planar manner.

14. The apparatus according to claim 13, further comprising:
a control module connected to the carrying module, the feeding module, and the at least one laser module; and
a monitoring module connected to the control module, wherein the monitoring module is configured to monitor a connection state between each of the plurality of conductive materials to be solidified and the corresponding one of the plurality of inner wall surfaces; and
wherein the monitoring module is configured to use a plurality of laser inspection beams having different delay times to probe morphological parameters of the at least one substrate, so as to monitor a bonding state between the inner wall surface of the at least one substrate and the conductive material to be solidified in real time.

15. The apparatus according to claim 13, further comprising:
a control module connected to the carrying module, the feeding module, and the at least one laser module; and
a monitoring module connected to the control module, wherein the monitoring module is configured to capture an image of at least one of the plurality of through holes to obtain a forming image;
wherein, when the monitoring module is configured to determine that the forming image conforms to a preset finished-product image, the monitoring module is configured to determine that the at least one of the plurality of through holes is a non-defective through hole;
wherein, when the monitoring module is configured to determine that the forming image does not conform to the preset finished-product image, the monitoring module is configured to determine that the at least one through hole is a defective through hole.

16. The apparatus according to claim 14, wherein the monitoring module comprises:
a light-emitting assembly configured to emit at least one first laser inspection beam and at least one second laser inspection beam toward the at least one substrate;
a first sensor configured to receive a reflected light of the at least one first laser inspection beam reflected by the at least one substrate to generate a reflected signal;
a second sensor configured to receive a transmitted light of the at least one second laser inspection beam passing through the at least one substrate to generate a transmitted signal; and
an image analysis assembly configured to receive the reflected signal to generate first inspection image data and receive the transmitted signal to generate second inspection image data.

17. The apparatus according to claim 16,
wherein the first sensor and the second sensor are optical wavefront sensors; and
wherein the first inspection image data includes a first inspection waveform diagram, and the second inspection image data includes a second inspection waveform diagram.

18. The apparatus according to claim 16,
wherein the first sensor and the second sensor are hyperspectral sensors;
wherein the image analysis assembly is a hyperspectral generator or a hyperspectral analysis device; and
wherein the first inspection image data and the second inspection image data respectively comprise a first inspection spectrum diagram and a second inspection spectrum diagram.

19. The apparatus according to claim 14, further comprising: an artificial intelligence module configured to learn and pre-train laser parameters of the at least one laser module, automatically select the monitoring module according to characteristics of the at least one substrate, and optimize settings of at least one monitoring parameter of the monitoring module.

20. The apparatus according to claim 19, wherein the artificial intelligence module comprises:
a database element having relevant data regarding a type, shape, size, thickness, and density of the at least one substrate;
a learning and training element connected to the database element and configured to perform learning and pre-training using a deep learning algorithm according to the relevant data in the database element;
a parameter optimization element connected to the database element and configured to optimize settings of the laser parameters according to the relevant data regarding the type, shape, size, thickness, and density of the at least one substrate; and
a monitoring setting element connected to the database element and configured to adjust the at least one monitoring parameter of the monitoring module according to the relevant data regarding the type, shape, size, thickness, and density of the at least one substrate.
